(19) United States
(12) Patent Application Publication
(10) Pub. No.: US 2008/0210169 A1
(43) Pub. Date: Sep. 4, 2008

(54) System for Supporting and Rotating a Susceptor Inside a Treatment Chamber of a Wafer Treating Apparatus

(75) Inventors: Vittorio Pozzetti, Brugherio (MI) (IT); Danilo Crippa, Novara (IT); Franco Preti, Milano (IT)

Correspondence Address: KATTEN MUCHIN ROSENMAN LLP, 575 MADISON AVENUE, NEW YORK, NY, 10022-2585, US

(73) Assignee: LPE S.P.A., Bollate (MI) (IT)

(21) Appl. No.: 11/995,891

(22) PCT Filed: Jul. 21, 2005
(86) PCT No.: PCT/IT2005/000425

§ 371 Date: Mar. 28, 2008

(51) Int. Cl. C23C 16/00

(52) U.S. Cl. 118/730

(57) ABSTRACT

The present invention relates to a system for supporting and rotating a susceptor within the treatment chamber of a wafer treatment apparatus comprising a support member (2) placed inside the treatment chamber and capable of supporting a susceptor (3), means (4) capable of lifting the support member (2) via a lifting gas flow, and means (5) capable of rotating the support member (2) via a rotation gas flow.

The present invention relates to a system for supporting and rotating a susceptor within the treatment chamber of a wafer treatment apparatus.

The present invention finds a particular application in epitaxial reactors, which are machines for depositing thin, uniform and regular layers of materials on wafers, termed in general in this case “substrates”; such machines are used for producing electrical components, in particular integrated circuits.

The epitaxial deposition material may be, for example, silicon [Si] or gallium nitride [GaN] or silicon carbide [SiC] and is produced starting from reaction gases which react in a reaction chamber.

The epitaxial deposition process takes place at high temperatures (typically above 800° C.); for some materials, such as silicon carbide, the temperatures are very high (typically above 1500° C.).

The substrates are placed inside the reaction chamber of the reactor on a support. In some reactors, the support participates actively in the heating of the substrates. In other reactors, the support participates passively in the heating of the substrates. The member which supports the substrates in the reaction chamber is generally termed a “susceptor”.

During the deposition process, the substrates are kept in motion in order to improve the uniformity and regularity of the layers deposited; in general, the susceptor rotates about an axis thereof.

In a first type of reactor, the susceptor always remains inside the reaction chamber; the substrates are inserted into the reaction chamber before the start of the deposition process, and are extracted from the reaction chamber at the end of the deposition process. In a second type of reactor, the susceptor is inserted, with the substrates to be treated, into the reaction chamber before the start of the deposition process, and is extracted with the treated substrates from the reaction chamber at the end of the deposition process.

For reactors of this second type, there is the problem of providing a simple and reliable system for handling the susceptor.

It is important to note that the deposition material is deposited not only on the substrates but also on the susceptor; the thickness of the layer deposited on the susceptor increases with each new deposition process; it has been observed by the Applicant that such deposition material, which accumulates on the susceptor, may cause slight but harmful deformations in the susceptor itself, especially in susceptors of discoid shape.

In order to solve the problem of deformation, the accumulated material may be removed periodically; this may be done for example by means of the use of hydrochloric acid; however, such a removal process takes time.

The general aim of the present invention is that of contributing to the solution of the problems described above, in particular in the case of susceptors of discoid shape.

A first specific aim of the present invention is that of providing a supporting and rotating system for susceptors which is little influenced by deformation of the susceptor.

A second specific aim of the present invention is that of providing a susceptor which deforms very little.

It is also an aim of the present invention to provide a solution which is suited also to treatment apparatus capable of operating at very high temperatures, such as epitaxial reactors for depositing silicon carbide.

These and other aims are achieved by the supporting and rotating system and by the susceptor having the features described in the claims appended hereto.

According to a further aspect, the present invention also relates to an apparatus for treating wafers in which such system and/or such susceptor are used.

The present invention will become clearer from the following description, to be considered conjointly with the drawings appended hereto, in which:

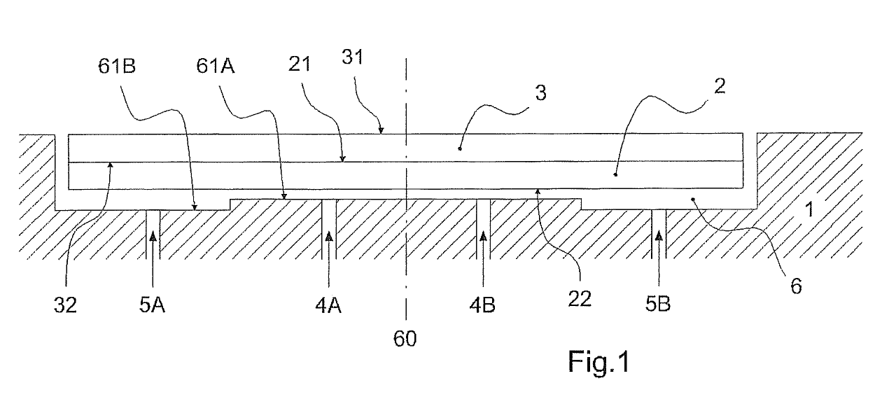

FIG. 1 shows a view in vertical section of a first system according to the present invention, with a susceptor,

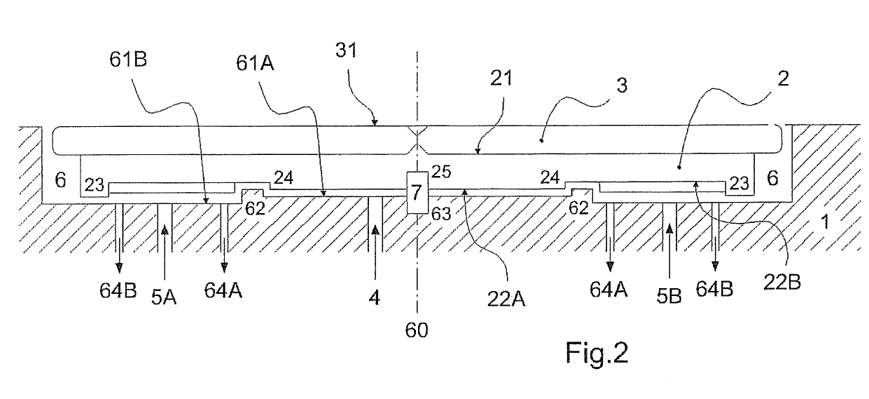

FIG. 2 shows a view in vertical section of a second system according to the present invention, with a susceptor,

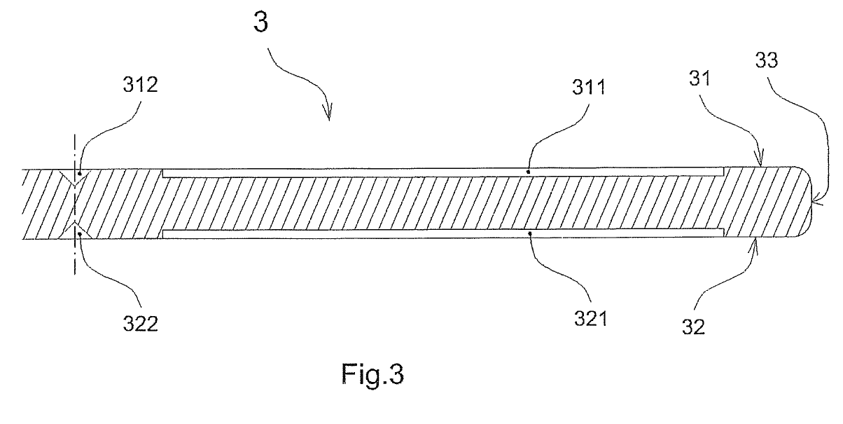

FIG. 3 shows a partial view in vertical section of a susceptor according to the present invention,

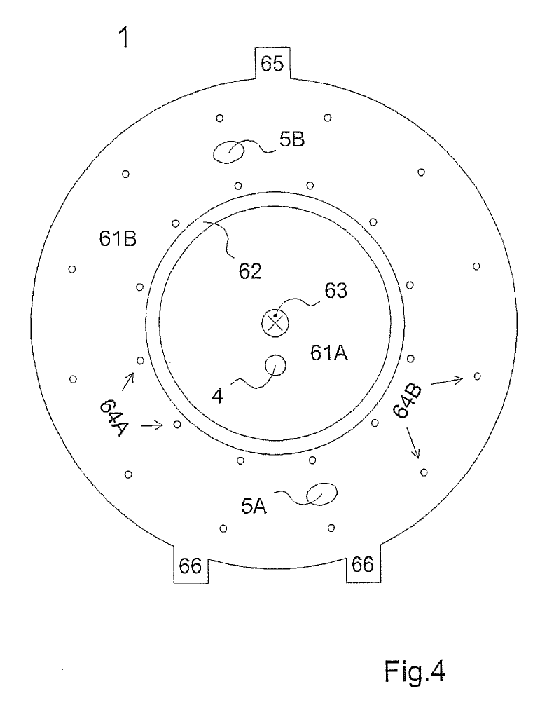

FIG. 4 shows a view from above of the system of FIG. 2 without support member,

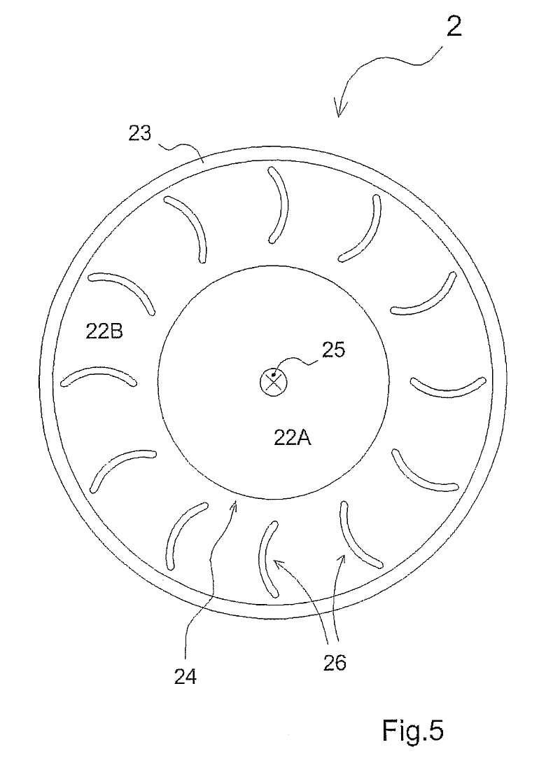

FIG. 5 shows a view from below of the support member of the system of FIG. 2, and

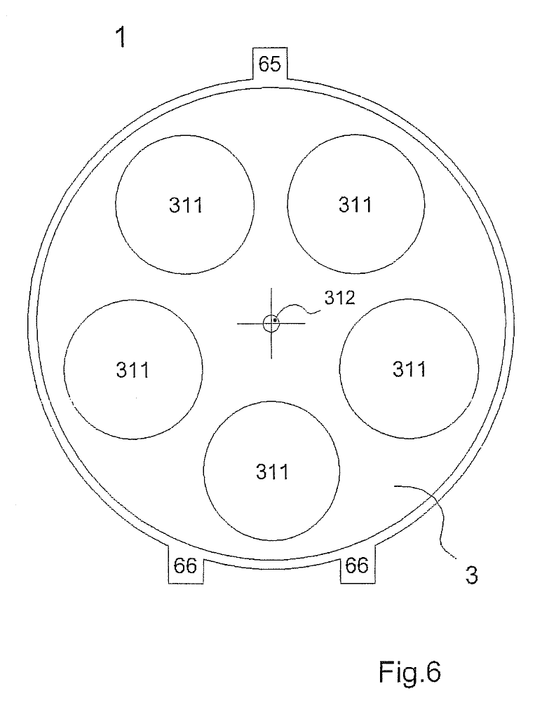

FIG. 6 shows a view from above of the system of FIG. 2 with the support member and a susceptor.

The description and drawings are to be considered solely by way of example and therefore as non-limiting; moreover, it is clear that the drawings are diagrammatic and not necessarily to scale.

FIG. 1 shows very diagrammatically a system according to the present invention. The reference number 1 indicates a wall of a reaction chamber of an epitaxial reactor disposed in a substantially horizontal position during the operation of the apparatus, that is, during the processes of deposition on the substrates. In the wall 1 an indentation 6 of substantially cylindrical shape is provided, having a bottom surface 61; the bottom surface 61 has a central region thereof 61A (in particular of circular shape) which is slightly raised, for example by 1-5 mm, with respect to a peripheral region thereof 61B (in particular annular in shape). Within the indentation 6 is housed a support member 2 of substantially discoid shape, and a susceptor 3 of substantially discoid shape placed on said support member 2. On the bottom surface 61 of the indentation 6 four pipes 4A, 4B, 5A, 5B open out; more precisely, the pipes 4A and 4B open out into the central region 61A in positions preferably symmetrical with respect to the axis 60 of the indentation 6, and the pipes 5A and 5B open out into the peripheral region 61B in positions preferably symmetrical with respect to the axis 60 of the indentation 6. The pipes 4A and 4B serve to conduct a lifting gas flow capable of lifting the member 2 and with it the susceptor 3 supported by the member 2, and any substrates supported by the susceptor 3. The pipes 5A and 5B serve to conduct a rotation gas flow capable of rotating the member 2 and with it the susceptor 3 supported by the member 2, and any substrates supported by the susceptor 3; the pipes 5A and 5B are inclined with respect to the axis 60 even if that is not visible in FIG. 1.

In the system of FIG. 1, the diameter of the member 2 is substantially equal to the diameter of the susceptor 3; naturally, the diameter of the indentation 6 must be suitably larger than the diameter of the member 2 and of the susceptor 3 so that these latter can rotate inside the indentation 6. The support member 2 has an upper surface 21 and a lower surface 22; the susceptor 3 has an upper surface 31 and a lower surface 32; in the example of FIG. 1, all these four surfaces are substantially plane; the numerical references relating to these surfaces will hereinafter be followed by the letter “A” when referring to a central region or by the letter “B” when referring to a peripheral region.

FIG. 2 shows slightly diagrammatically a system according to the present invention; this system differs a little from that in FIG. 1; analogous elements of these two systems are associated with the same numerical references. It will be noted that the susceptor 3 has a diameter slightly larger than the diameter of the member 2, that a single pipe 4 is provided for the lifting gas flow and that it opens out in the vicinity of the axis 60, that the bottom surface 61 of the indentation 6 is more shaped, that the lower surface 22 of the member 2 is suitably shaped, and that there are guide means, in particular a guide pin 7 in the centre of the indentation 6, for guiding the rotation of the member 2.

The central region 61A of the surface 61 is surrounded by a barrier 62 which is slightly raised, for example by 0.5-1.5 mm. The lower surface 22 of the member 2 has a peripheral region thereof 22B (in particular of annular shape) which is slightly lowered, for example by 0.5-1.5 mm with respect to a central region thereof 22A (in particular of circular shape); between the region 22A and the region 22B a step 24 (in particular of circular shape) is therefore defined; the annular region 22B is surrounded by a barrier 23, raised for example by 1-5 mm; the step 24 is within the barrier 62, in particular the diameter of the step 24 is suitably smaller than the inside diameter of the barrier 62, such as to permit rotation but to hinder the passage of gas. A seat 25 for the pin 7 is provided on the member 2, and a seat 63 for the pin 7 is provided on the wall 1, within the indentation 6. Preferably, the pin 7 is not joined either to the wall 1 or to the member 2; alternatively, the pin 7 could be incorporated or built into or screwed to the wall 1 or the member 2. The example of FIG. 2 shows centring means capable of permitting the centred positioning of the susceptor 3 on the member 2, in particular, a conical pin placed in the centre of the upper surface 21 of the member 2.

Both in the system of FIG. 1 and in the system of FIG. 2, the reaction gases flow over the upper surface 31 of the susceptor 3, preferably in a direction substantially parallel to that surface.

FIG. 3 shows a susceptor according to the present invention which lends itself to being used both with the system of FIG. 1 and with the system of FIG. 2. The susceptor 3 is of substantially discoid shape and has an upper face 31, a lower face 32 and a lateral rim 33; the edges between the face 31, the face 32 and the rim 33 are rounded off. In the particular example of FIG. 3, the susceptor 3 is perfectly symmetrical in a vertical direction. On the face 31 recesses 311 for substrates are provided; on the face 32 recesses 321 for substrates are provided in positions aligned with the recesses 311. On the face 31 centring means are provided which are capable of permitting the centred positioning of the susceptor 3 on a support member, in particular a conical indentation 312 in the centre of the face 31; on the face 32 centring means are provided which are capable of permitting the centred positioning of the susceptor 3 on a support member, in particular a conical indentation 322 in the centre of the face 32.

FIG. 4 shows the system of FIG. 2 without the support member 2. The indentation 6 provided in the wall 1 can be seen, the surface 61 sub-divided into a central region 61A and a peripheral region 61B, the rim 62, the seat 63 for the pin 7, the outlets of the pipes 4, 5A and 5B; the pipe 4 is circular in section and is substantially parallel to the axis 60; since the pipes 5A and 5B are inclined with respect to the axis 60, their outlets are elliptical in shape, even if their section is circular.

The pipes 4, 5A and 5B are branchings of the same inlet pipe (not visible in the drawings) which is capable of conducting both the lifting gas flow and the rotation gas flow; in FIG. 4, said inlet pipe is not visible because it is below the surface 61 and is disposed in a vertical direction with respect to the arrangement of the drawing; the outlets of the pipes 5A and 5B are slightly displaced laterally with respect to the single inlet pipe because of their inclination. Onto the bottom surface 61 of the indentation 6, in particular in its peripheral region 61B, open two series of holes 64; the first series 64A is disposed uniformly along a circumference close to the edge 62; the second series 64B is disposed uniformly along a circumference close to the edge of the indentation 6; the holes 64 serve to discharge the gas of the lifting flow and the gas of the rotation flow after they have performed their task. The holes 64 terminate in the same outlet pipe (not visible in the drawings) which extends beneath the wall 1 at least at the support member 2, or substantially at least at the indentation 6; in the example of FIG. 2 and FIG. 4, even if it is not visible, the outlet pipe extends substantially beneath the entire wall 1.

On the edge of the indentation 6 three notches are provided, in particular a front notch 65 and two rear notches 66; the notches serve to introduce engagement members (for example in the form of teeth) of a tool mounted on the arm of a robot for handling the susceptor 3.

FIG. 5 shows the support member 2 of the system of FIG. 2 from below. The lower surface 22 can be seen, sub-divided into a central region 22A and a peripheral region 22B, the rim 23, and the seat 25 for the pin 7.

On the surface 22, in particular in its peripheral region 22B, there are a series of protuberances 26 disposed uniformly like spokes; the protuberances 26 of the example of FIG. 5 are arcuate in shape. The protuberances have the purpose of receiving the rotation gas flow and transforming it into rotation of the member 2.

FIG. 6 corresponds exactly to FIG. 4, with the difference that in the indentation 6 there has been placed the support member 2 of FIG. 5 and the susceptor 3 of FIG. 3.

The system in the drawings provides for the susceptor 3 to be placed on the support member 2; on the susceptor 3 are placed substrates on which epitaxial deposition processes are to be carried out. During the treatment, gas is caused to flow in the pipes 4 and in the pipes 5. The gas emerges from the pipes 4, impinges vertically on the central region 22A of the lower surface 22 of the member 2 and slightly raises the member 2 and with it the susceptor 3 and the substrates; then the gas flows laterally towards the peripheral regions 22B and 61B respectively of the surfaces 22 and 61. The gas emerges from the pipes 5, impinges obliquely on the peripheral region 22B of the lower surface 22 of the member 2 and rotates the member 2 and with it the susceptor 3 and the substrates. The gas coming from the pipes 4 and from the pipes 5 then flows into the outlet pipe through the holes 64.

For the purpose of the technical effects described above, an important part is played by the barrier 62, the step 24, the barrier 23 and the protuberances 26. The barrier 62 constitutes a wall of a pressure chamber below the central region 22A of the lower surface 22 of the member 2; the barrier 62 in combination with the step 24 form a labyrinthine wall. The barrier 23 hinders the gas coming from the pipes 4 and 5 from flowing along the edge of the indentation 6 into the reaction chamber. The protuberances 26, in an effective and efficient manner, transform the flow of gas coming from the pipes 5 into rotation of the member 2.

Referring to FIG. 2 and FIG. 6, it will be understood that the engagement members of a tool may easily be introduced into the notches 65 and 66; such engagement members can then easily grip the susceptor 3, since the rim of the susceptor 3 protrudes from the rim of the support member 2. It is therefore easy both to place the susceptor 3 on the support 2, in particular by inserting it into the indentation 6, and to remove the susceptor 3 from the support member 2, in particular by withdrawing it from the indentation 6.

The system, according to the present, invention serves to support and rotate a susceptor within the treatment chamber of a wafer treatment apparatus.

In general, the system according to the present invention comprises:
a support member placed inside said treatment chamber and capable of supporting a susceptor,
means capable of lifting said support member via a lifting gas flow, and
means capable of rotating said support member via a rotation gas flow.

According to this solution, the rotation of the susceptor is effected without the use of complicated and delicate mechanical transmissions which often require at least one large hole in a wall of the reaction chamber. Furthermore, the rotation of the susceptor is not influenced either by its shape or by its dimensions, since the means which give rise to the movement of the susceptor do not place restraints on the susceptor itself. Moreover, since the lifting means are separate from the rotating means, the two can be designed independently in such a way as to optimize the two technical effects. Finally, since the susceptor is fairly independent of the support member, it is easier to design the system for handling the susceptor; in fact, the susceptor may be modified in part in order to adapt better to being handled.

The system according to the present invention may also comprise a wall of the treatment chamber, in particular the wall which is capable of being substantially horizontal during the treatment processes; the wall is provided with an indentation of substantially cylindrical shape; in this case, the support member is of substantially discoid shape and is inserted into the indentation; preferably, the susceptor will also be of substantially discoid shape. This is the case in the examples of the drawings, in particular of the wall 1, the indentation 6, the member 2 and the susceptor 3.

Preferably, the indentation in the wall has a depth such as to substantially receive both the support member and the susceptor.

In this way, the reaction gas flows in the reaction chamber are not influenced by the system according to the present invention, since the susceptor does not protrude from the wall. This is the case in the examples in the drawings.

It is advantageous to provide, for the lifting gas flow and rotation gas flow, to come from separate supplies. In this way, the two technical effects can be controlled independently of each other by regulating the respective supplies.

In the case of the example of FIG. 2, the pipes 4, 5A and 5B are branchings of the same inlet pipe that is connected to a single supply. Alternatively, the pipe 4 could be connected to a first supply and the pipes 5A and 5B could be connected together to a second supply; the two supplies, for example two mass flow controllers [MFCs], may be connected to the same tank of gas, for example hydrogen or helium or argon.

The support member may be provided with protuberances and/or indentations capable of receiving a rotation gas flow and of transforming it into rotation of the support member. This is the case in the example of FIG. 5, in particular of the protuberances 26 which receive the flow of gas which emerges in an inclined direction from the pipes 5A and 5B; it is substantially a simple turbine produced on the lower surface 22 of the support member 2.

Preferably, the protuberances and/or the indentations are in a lower peripheral region of the support member. This is the case in the example of FIG. 5. In this way, the rotation gas flow transmits a high value moment to the support member since it impinges on the protuberances and/or the indentations far from the axis of rotation (indicated by 60 in the drawings) and therefore with a long lever arm.

The support member may be equipped with a surface capable of receiving a lifting gas flow and of transforming it into lifting of the support member. Preferably, this surface is in a lower central region of the support member. This is the case in the examples in the drawings. In this way, the gas flow is very efficient for the purpose of lifting.

It is advantageous to provide, for the lower peripheral region of the support member which receives the rotation gas flow, to be separate from the lower central region of the support member which receives the lifting gas flow. This is the case in the examples in the drawings. In this way, it is possible to shape the two surface regions independently and to optimize the two technical effects. In the example of FIG. 2 and FIG. 5, the shaping is well differentiated and barriers, steps, protuberances and indentations are provided.

The system according to the present invention may comprise means capable of not discharging the gas of the lifting flow or of the rotation flow (preferably both) into the treatment chamber; these means may be provided on the support member and/or on the wall of the reaction chamber, in particular in the indentation. This is the case in the examples in the drawings (even if it is not visible in FIG. 1); in the example of FIG. 2 and of FIG. 4, such means are constituted by the barrier 23 and the holes 64. In this way, the gas of the lifting flow and of the rotation flow does not “pollute” the atmosphere of the reaction chamber; therefore, the capacity and velocity of these flows may be selected fairly freely.

A simple but very effective method for producing the means described above consists in providing an outlet pipe which extends beneath a wall of the reaction chamber at least at the support member and which is capable of discharging the gas of the lifting flow and/or of the rotation flow. This is the case in the example of FIG. 4; the holes 64 place the space between the indentation 6 and the support member 2 in communication with the outlet pipe.

It is advantageous to provide for the support member to comprise centring means capable of permitting the centred positioning of the susceptor on the support member. This may be effected in various ways; it is possible, for example, to provide one or more centring protuberances on the upper surface of the support member (and one or more corresponding indentations on the surface of the susceptor)—one of these could be central; it is possible, for example, to provide three or more small teeth placed at the edge of the support member.

It is advantageous to provide guide means in the system according to the present invention, in particular a central pin, capable of guiding the rotation of the support member. This is the case in the example of FIG. 2, in particular of the central pin 7. Such guide means may not be fixed; alternatively, they may be incorporated in, or joined to, the wall of the reactor or the support member.

The system according to the present invention is particularly suitable for being used in cases in which the support member is capable of remaining inside the treatment chamber and in which the susceptor is capable of being introduced into, and withdrawn from, the reaction chamber. In fact, the susceptor is advantageously simply placed on the support member.

The susceptor according to the present invention serves for a wafer treatment apparatus, in particular for an epitaxial reactor.

In general, the susceptor according to the present invention comprises recesses for receiving wafers to be treated and is substantially in the shape of a disc provided with a first face and a second face; at least one of said recesses is provided on the first face and at least one of said recesses is provided on the second face. It is then a question of a double-face susceptor which may advantageously be used in combination with the supporting and rotating system defined before, by the fact that it can simply be placed on the support member.

If both the faces of the susceptor are used, for example alternately, the spurious growths occur on both the faces and therefore the deformations are fairly limited, since the effects of the spurious growths on the two faces compensate one another.

Furthermore, since the support member is completely covered by the susceptor, this is protected from spurious growths and therefore its rotation is not substantially influenced by the spurious growths.

Preferably, the recesses on the first face are in positions aligned respectively with the recesses on the second face. This is the case in the example of FIG. 3. In this way, the uniformity of heating of the wafers is maximized.

However, it is also possible to provide that:
A) on a first face of the susceptor there are several recesses, for example for four-inch wafers, and on a second face there are several recesses, for example for six-inch wafers, or
B) on a first face of the susceptor there are several recesses, for example for four-inch wafers, and on a second face there is a single recess, for example for an eight-inch wafer.

It is advantageous to provide, for the susceptor according to the present invention, to comprise centring means capable of permitting the centred positioning of the susceptor on a support member.

There are various possibilities for producing such centring means. The susceptor may comprise at least one centring hole located in particular at the centre of the disc. The susceptor may comprise, on each of the faces, at least one centring indentation of preferably substantially conical shape, in particular located at the centre of the disc. In the case where one or the only wafer must be positioned at the centre of the susceptor, such centring means should not be positioned at the centre of the susceptor.

As already pointed out, it is important to be able to handle the susceptor in a simple and reliable manner in order to be able to withdraw it from, and insert it into, a treatment chamber of a wafer treatment apparatus, in particular a reaction chamber of an epitaxial reactor.

A first solution which lends itself particularly well to being used (but not only) with the susceptor according to the present invention is based on a tool equipped with one or more suction cups; these must adhere to the surface of the susceptor not occupied by the recesses for wafers; the simplicity of the structure of the susceptor according to the present invention facilitates the use of this solution for both faces of the susceptor.

A second solution which lends itself particularly well to being used (but not only) with the susceptor according to the present invention is based on a tool equipped with engagement members, for example in the form of teeth, for gripping the susceptor by its edge; the presence, in the system according to the present invention, of a support member independent of the susceptor facilitates the use of this solution.

A third solution which lends itself particularly well to being used with the susceptor according to the present invention provides for the susceptor to comprise a protruding member, preferably mushroom-shaped, capable of being gripped by a tool and capable of being fitted removably and in such a way as to protrude alternatively from its first face or from its second face; naturally, it will then be necessary to provide a tool capable of gripping such a protruding member, for example with a forked end or with a pincer-like end.

Each of the tools mentioned above may be mounted at the end of an arm of a robot so as to produce a system for automatic handling of the susceptor.

As already stated, an apparatus for treating wafers also constitutes an aspect of the present invention.

This may comprise a supporting and rotating system such as that defined before or a susceptor such as that defined before.

Naturally, according to the form of embodiment preferred, the apparatus comprises both such a system and such a susceptor placed on the support member of the system.

Typically, an apparatus for treating wafers, in particular an epitaxial reactor, is equipped with a system for handling the susceptor.

If provision is made to use a tool equipped with engagement members, for example in the form of teeth, it is advantageous to provide, for the horizontal wall of the treatment chamber, on which (for example in an indentation) the susceptor and/or the support member rests, to be equipped with notches (or, more generally, with indentations) in order to be able to introduce the engagement members easily and grip the susceptor by the edge.

1. A system for supporting and rotating a susceptor within the treatment chamber of a wafer treatment apparatus, comprising:
a support member (2) placed inside said treatment chamber and capable of supporting a susceptor (3),
a susceptor (3) placed on said support member (2) into contact therewith through respective horizontal surfaces (21, 32);
means (4) capable of lifting said support member (2) and with it said susceptor (3) via a lifting gas flow, and
means (5) capable of rotating said support member (2) and with it said susceptor (3) via a rotation gas flow.

2. A system according to claim 1, wherein a wall (1) of said treatment chamber is provided with an indentation (6) of substantially cylindrical shape, wherein said susceptor (3) is of preferably substantially discoid shape, and wherein said support member (2) is of substantially discoid shape and is inserted into said indentation (6).

3. A system according to claim 2, wherein said indentation (6) has a depth such as to substantially receive both said support member (2) and said susceptor (3).

4. A system according to claim 1, wherein said gas flows come from separate supplies.

5. A system according to claim 1, wherein said support member (2) is provided with protuberances (26) and/or indentations capable of receiving a rotation gas flow and of transforming it into rotation of the support member (2).

6. A system according to claim 5, wherein said protuberances (26) and/or indentations are in a lower peripheral region (22B) of the support member (2).

7. A system according to claim 1, wherein said support member (2) is provided with a surface (22A) capable of receiving a lifting gas flow and of transforming it into lifting of the support member (2).

8. A system according to claim 7, wherein said surface (22A) is in a lower central region of the support member (2).

9. A system according to claim 6, wherein said lower peripheral region (22B) is separate from said lower central region (22A).

10. A system according to claim 1, comprising means (23, 64) capable of not discharging the gas of said lifting flow and/or of said rotation flow into said treatment chamber.

11. A system according to claim 10, comprising:
a wall (1) of said treatment chamber on which said support member (2) is placed, and
an outlet pipe which extends beneath said wall (1) at least at said support member (2) and which is capable of discharging the gas of said lifting flow and/or of said rotation flow.

12. A system according to claim 1, wherein said support member (2) comprises centring means capable of permitting the centred positioning of the susceptor (3) on the support member (2).

13. A system according to claim 1, comprising guide means, in particular a central pin (7), capable of guiding the rotation of the support member (2).

14. A system according to claim 1, wherein the support member (2) is capable of remaining inside the treatment chamber and wherein the susceptor (3) is capable of being introduced into, and withdrawn from, the reaction chamber.

15. A susceptor (3) for a wafer treatment apparatus comprising recesses for receiving wafers to be treated and being substantially in the shape of a disc provided with a first face (31) and a second face (32), characterized in that at least one (311) of said recesses is provided on said first face (31) and that at least one (321) of said recesses is provided on said second face (32).

16. A susceptor according to claim 15, wherein the recesses on said first face (31) are in positions aligned respectively with the recesses on said second face (32).

17. A susceptor according to claim 15, comprising centring means (312, 322) capable of permitting the centred positioning of the susceptor (3) on a support member (2).

18. A susceptor according to claim 17, comprising at least one centring hole.

19. A susceptor according to claim 18, wherein said hole is located at the centre of said disc.

20. A susceptor according to claim 17, comprising, on each of said faces (31, 32), at least one centring indentation (312, 322) of preferably substantially conical shape.

21. A susceptor according to claim 20, wherein said indentation (312, 322) is located at the centre of said disc.

22. A susceptor according to claim 15, comprising a protruding member capable of being gripped by a tool and capable of being fitted removably and in such a way as to protrude alternatively from said first face (31) or from said second face (32).

23. An apparatus for treating wafers, comprising a system comprising
a support member (2) placed inside said treatment chamber and capable of supporting a susceptor (2 3),
a susceptor (3) placed on said support member (2) into contact therewith through respective horizontal surfaces (21, 32);
means (4) capable of lifting said support member (2) and with it said susceptor (3) via a lifting gas flow, and
means (5) capable of rotating said support member (2) and with it said susceptor (3) via a rotation gas flow.

24. An apparatus for treating wafers, comprising a susceptor comprising
recesses for receiving wafers to be treated and being substantially in the shape of a disc provided with a first face (31) and a second face (32), characterized in that at least one (311) of said recesses is provided on said first face (31) and that at least one (321) of said recesses is provided on said second face (32).

25. An apparatus for treating wafers, comprising a system comprising
a support member (2) placed inside said treatment chamber and capable of supporting a susceptor (2 3),
a susceptor (3) placed on said support member (2) into contact therewith through respective horizontal surfaces (21, 32);
means (4) capable of lifting said support member (2) and with it said susceptor (3) via a lifting gas flow, and
means (5) capable of rotating said support member (2) and with it said susceptor (3) via a rotation gas flow,
and a susceptor comprising
recesses for receiving wafers to be treated and being substantially in the shape of a disc provided with a first face (31) and a second face (32), characterized in that at least one (311) of said recesses is provided on said first face (31) and that at least one (321) of said recesses is provided on said second face (32),
the susceptor placed on the support member of said system.
